(19) United States
(12) Patent Application Publication
(10) Pub. No.: US 2026/0314477 A1
(43) Pub. Date: Oct. 8, 2026

(54) SEMICONDUCTOR PACKAGE HAVING A MULTI-LAYER FILM STRUCTURE

(71) Applicant: Sandisk Technologies, Inc., Milpitas, CA (US)

(72) Inventors: Jihao Tang, Shanghai (CN); Yuanheng Zhang, Shanghai (CN); Shaopeng Dong, Shanghai (CN); Rui Guo, Shanghai (CN); Wenbin Qu, Shanghai (CN); Weng Khoon Mong, Penang (MY)

(21) Appl. No.: 19/173,532

(22) Filed: Apr. 8, 2025

(51) Int. Cl. H10W 74/10; H10W 46/00; H10W 74/01; H10W 90/00; H10W 70/60; H10W 72/00; H10W 72/50; H10W 90/20; H10W 90/24

(52) U.S. Cl. CPC H10W 74/147; H10W 46/00; H10W 74/01; H10W 74/121; H10W 90/00; H10W 70/60; H10W 70/611; H10W 72/07553; H10W 72/531; H10W 90/24; H10W 90/288; H10W 90/752; H10W 90/754

(57) ABSTRACT

A semiconductor package includes a multi-layer film structure that facilitates clearance reduction for the semiconductor package and protects bond wires extending beyond a top surface of the top semiconductor die from short-circuiting. The multi-layer film structure also prevents burning or other visual defects that may occur when bond wires contact other structures. The multi-layer film structure includes a first layer that contacts a portion of the bond wire. A second layer of the multi-layer film structure provides rigidity. The multi-layer film structure also includes a third layer that facilitates marking of the semiconductor package.

### BACKGROUND

Semiconductor packages, such as non-volatile memory devices, are used in various electronic devices such as cellular telephones, digital cameras, personal digital assistants, medical electronics, mobile computing devices, and the like. Because of its inclusion in most modern electronic devices, the demand for semiconductor packages is increasing. Additionally, as processing expectations increase and the size of electronic devices decrease, the desire for higher capacity, smaller size, and higher performance of these semiconductor packages increases with demand. However, it is increasingly difficult to reduce the size of the semiconductor package without sacrificing the capacity, stability, and/or reliability of the semiconductor package.

For example, in order to increase the capacity of a non-volatile memory device, additional semiconductor dies are added to a stack of semiconductor dies included with the non-volatile memory device. However, as additional semiconductor dies are added to the stack, the thickness or height of the semiconductor package increases. Additionally, as these stacks are incorporated into other structures, a clearance between the top of the stack (e.g., a top clearance) and the other structures is needed to preserve functionality. For example, if the clearance between the top of the stack and the other structures is too low, the stack may experience die burn and other defects (e.g., visual defects, etc.), causing yield loss. If the clearance between the top of the stack and the other structures is too high, the overall package size (e.g., thickness) increases.

Accordingly, it would be beneficial for a semiconductor package having stacked semiconductor dies with reduced clearance to incorporate the semiconductor package into other structures, thus balancing a thickness of the semiconductor package while preserving processing capabilities of the semiconductor package.

### SUMMARY

The present disclosure generally relates to a semiconductor package, and more particularly, to a stacked semiconductor package including a multi-layer film structure. The multi-layer film structure is disposed over a top semiconductor die of the semiconductor package, thereby facilitating a reduction in clearance for the semiconductor package when compared with current solutions.

In an example, the semiconductor package includes a multi-layer film structure that facilitates clearance reduction for the semiconductor package. Inclusion of the multi-layer film structure protects bond wires extending beyond a top surface of the top semiconductor die in the semiconductor package. Specifically, the multi-layer film structure protects the bond wires from short-circuiting or burning or other visual defects due to contact of the bond wires with other structures. The multi-layer film structure may include a first, protective layer that contacts a portion of a bond wire at the top surface. The multi-layer film structure can also include a second layer formed above the first layer. In an example, the second layer provides rigidity to the multi-layer film structure and also protects the first layer that contacts and/or receives the bond wires. Optionally, the multi-layer film structure includes a third layer formed over the second layer. The third layer facilitates marking or etching of the semiconductor package as well as providing further protection from die burn or short-circuiting of the semiconductor package.

Accordingly, examples of the disclosure provide a semiconductor package that includes a substrate and a plurality of stacked semiconductor dies disposed over the substrate. In an example, the plurality of stacked semiconductor dies include a top semiconductor die positioned above the substrate. The top semiconductor die includes a top surface and a semiconductor die contact formed on the top surface. A multi-layer film structure is disposed over the top semiconductor die and includes an insulative layer disposed directly over the top surface of the top semiconductor die and a metallic layer disposed directly over the insulative layer. A bond wire contacts the semiconductor die contact of the top semiconductor die. In an example, at least a portion of the bond wire contacts the insulative layer of the multi-layer film structure.

Additional examples describe a method of manufacturing a semiconductor package. In an example, the method includes disposing a plurality of stacked semiconductor dies on a substrate. The plurality of stacked semiconductor dies includes a top semiconductor die positioned above the substrate. In an example, the top semiconductor die includes a top surface and a semiconductor die contact formed on the top surface. The method also includes connecting a portion of a bond wire to the semiconductor die contact of the top semiconductor die and disposing a multi-layer film structure directly over the top semiconductor die of the plurality of stacked semiconductor dies. In an example, an insulative layer of the multi-layer film structure contacts the portion of the bond wire connected to the semiconductor die contact of the top semiconductor die.

Still other examples describe an encapsulated semiconductor package that includes a substrate including a first contact means and a plurality of stacked semiconductor dies disposed over the substrate. In an example, the plurality of stacked semiconductor dies includes a top semiconductor die positioned above the substrate. The top semiconductor die includes a top surface and a second contact means provided on the top surface. A connection means extends between and electrically connecting the second contact means of the top semiconductor die and the first contact means of the substrate. An insulative means is disposed directly over the top semiconductor die. The insulative means contacts a portion of the connection means. A resistance means is disposed directly over the insulative means.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a perspective view of a semiconductor package including a multi-layer film structure, according to an example.

FIG. 2 shows a front cross-sectional view of the semiconductor package of FIG. 1 taken along line 2-2, according to an example.

FIG. 3 shows a front cross-sectional view of the semiconductor package of FIG. 1 taken along line 3-3, according to an example.

FIGS. 4-5 show front cross-sectional views of the semiconductor package including a multi-layer film structure according to an example.

FIG. 6 shows a flowchart illustrating processes for creating semiconductor packages including a multi-layer film structure, according to an example.

FIGS. 7-10 show front cross-sectional views of an encapsulated semiconductor package undergoing processes for creation similar to those shown in FIG. 6, according to an example.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

As an initial matter, in order to clearly describe the current disclosure, it will become necessary to select certain terminology when referring to and describing relevant components within the disclosure. When doing this, if possible, common industry terminology will be used and employed in a manner consistent with its accepted meaning. Unless otherwise stated, such terminology should be given a broad interpretation consistent with the context of the present application and the scope of the appended claims. Those of ordinary skill in the art will appreciate that often a particular component may be referred to using several different or overlapping terms. What may be described herein as being a single part may include and be referenced in another context as consisting of multiple components. Alternatively, what may be described herein as including multiple components may be referred to elsewhere as a single part.

As discussed herein, the disclosure relates generally to semiconductor packages, and more particularly, to semiconductor packages including multi-layer film structures disposed over a top surface of the semiconductor package and/or a top surface of a semiconductor die of the semiconductor packages. In an example, the multi-layer film structure provides an insulative layer that contacts and/or receives a portion of the bond wires included in the semiconductor packages. That is, portions of the bond wires of the semiconductor package contact, extend through and/or are secured or embedded within the insulative layer of the multi-layer film structure. The insulative layer reduces the risk of short-circuiting of the bond wires within the semiconductor package during operation. In the example, the multi-layer film structure also provides a resistant layer formed over the insulative layer. The resistant layer provides protection to the insulative layer itself and protection to the semiconductor package during a laser etching process. Collectively, the insulative layer and the resistant layer forming the multi-layer film structure can include a predetermined height or thickness that is smaller than conventional materials disposed over top semiconductor dies for conventional semiconductor packages. The multi-layer film structure may additionally include an marking layer to facilitate marking of the semiconductor package.

Accordingly, many technical benefits may be realized including, but not limited to, decreasing top clearances for both the top semiconductor die and bond wires connected or coupled to the top semiconductor die. This reduces the loop height of the wires that contact the insulative layer, and ultimately reduces the overall height or thickness of the semiconductor package itself. Further, incorporation of the multi-layer film structures protects semiconductor packages from die burn when the packages undergo marking or etching processes. Still further, the multi-layer film structure can be added to semiconductor packages using pre-existing assembly lines and processes, further streamlining the manufacturing process for semiconductor packages.

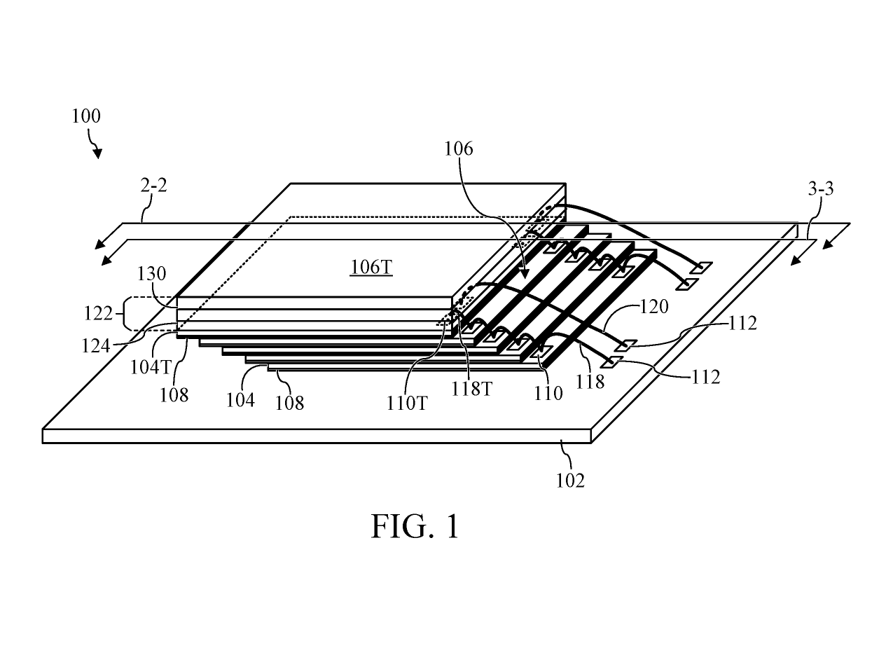

These and other examples are discussed below with reference to FIGS. 1-10. However, those skilled in the art will readily appreciate that the detailed description given herein with respect to these Figures is for explanatory purposes only and should not be construed as limiting.

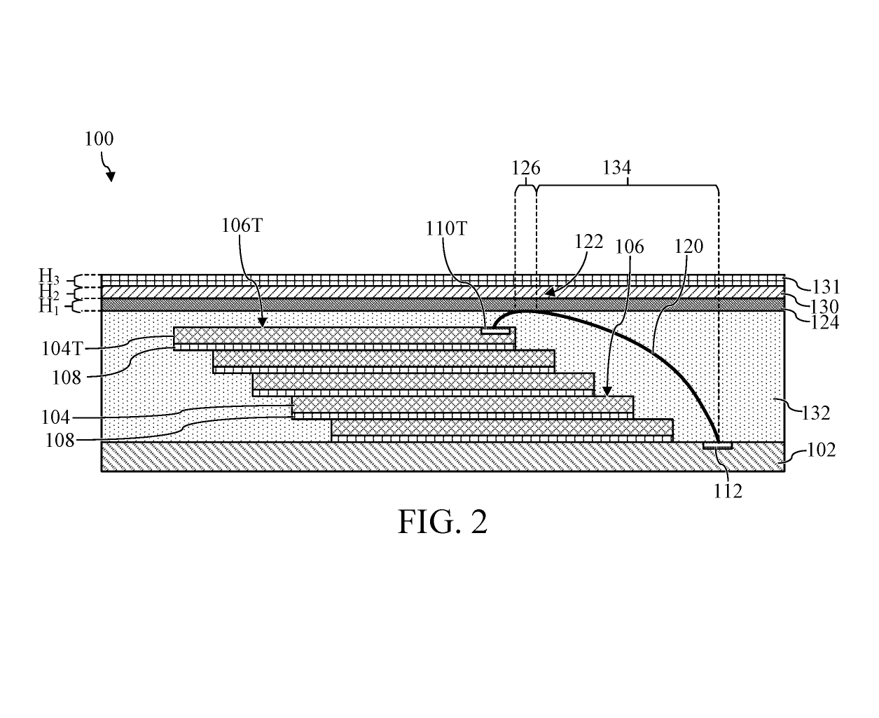

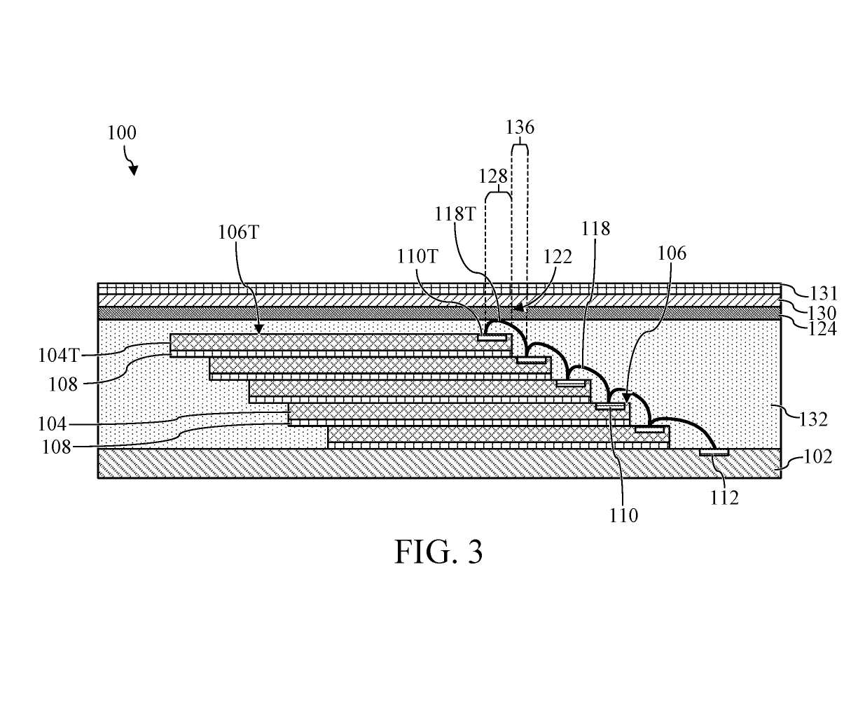

Turning to FIGS. 1-3, a semiconductor package 100 is shown in various views. More specifically, FIG. 1 shows a perspective view of semiconductor package 100, FIG. 2 shows a cross-sectional front view of semiconductor package 100 taken along line 2-2 in FIG. 1, and FIG. 3 shows a cross-sectional front view of semiconductor package 100 taken along line 3-3 in FIG. 1. Semiconductor package 100 shown in FIG. 1 has omitted the inclusion of a molding compound (see, FIGS. 2 and 3) for ease of view of the other components or structures of semiconductor package 100. As discussed herein, semiconductor package 100 includes a molding compound that substantially surrounds and/or is disposed over some of the various components or structures of the semiconductor package 100.

In the non-limiting example, semiconductor package 100 includes a substrate 102. Substrate 102 forms the base layer for semiconductor package 100. Substrate 102 is formed as a semiconducting material and/or is formed from any suitable material or material composition that includes semiconducting properties/characteristics.

Semiconductor package 100 also includes a plurality of stacked semiconductor dies 104, 104T. As shown in FIGS. 1-3, the plurality of stacked semiconductor dies 104, 104T are disposed over, positioned on, and/or formed above substrate 102. In the non-limiting example, the plurality of stacked semiconductor dies 104, 104T are staggered or stepped with respect to one another when disposed over substrate 102. As such, at least a portion of a top surface 106 for each semiconductor die of the plurality of stacked semiconductor dies 104 is uncovered by the adjacent semiconductor die 104 positioned thereon. As discussed herein, additional materials and/or structures cover the uncovered top surfaces 106 of the plurality of stacked semiconductor dies 104 in semiconductor package 100 (e.g., molding compound 132 (FIG. 2)). Additionally, and as shown, the plurality of stacked semiconductor dies 104, 104T includes a top semiconductor die 104T positioned opposite and/or above the substrate 102, and is formed over all remaining semiconductor dies of the plurality of stacked semiconductor dies 104. Top semiconductor die 104T of the plurality of stacked semiconductor dies 104, 104T includes a top surface 106T. A molding compound 132 may cover or substantially cover the top surface 106T and a multi-layer film structure 122 is at least partially provided over the molding compound 132.

In a non-limiting example, the plurality of stacked semiconductor dies 104, 104T of semiconductor package 100 are formed as NAND memory dies. However, it is understood that the plurality of stacked semiconductor dies 104, 104T can be formed as any volatile or non-volatile memory die, or any other suitable circuit stack-up configuration. Additionally in the non-limiting example shown in FIGS. 1-3, the plurality of stacked semiconductor dies 104, 104T includes five (5) dies. It is understood that the number of semiconductor dies included in the plurality of stacked semiconductor dies 104 is illustrative, and semiconductor package 100 can include any suitable number of semiconductor dies to form the stacked semiconductor dies 104, 104T. Furthermore, although only a single plurality of stacked semiconductor dies 104, 104T are shown in FIGS. 1-3, it is understood that semiconductor package 100 can include more than one plurality of stacked semiconductor dies 104, where each of the plurality of stacked semiconductor dies 104 is disposed or formed over substrate 102, adjacent to one another.

As shown in FIGS. 1-3, semiconductor package 100 also includes a plurality of semiconductor die attach films (DAF) 108 (hereafter, “DAF 108”). Each of the plurality of DAF 108 is disposed between each of the plurality of stacked semiconductor dies 104, 104T and/or between semiconductor die 104 and substrate 102. More specifically, DAF 108 are disposed over and/or substantially cover a bottom surface of each of the plurality of stacked semiconductor dies 104, 104T, opposite top surface 106, 106T, to bond or connect semiconductor dies 104, 104T to adjacent semiconductor dies 104 and/or substrate 102. In a non-limiting example, DAF 108 coupled to the top semiconductor die 104T directly contacts the top surface 106 of an adjacent semiconductor die 104 to bond and/or connect the top semiconductor die 104T to the adjacent semiconductor die 104. Additionally, semiconductor die 104 positioned adjacent substrate 102 is coupled and/or connected directly to substrate 102 via DAF 108. DAF 108 is formed as any suitable adhesive material capable of withstanding the operational parameters, characteristics, and/or constraints (e.g., temperature change) of semiconductor package 100.

Each of the plurality of stacked semiconductor dies 104, 104T includes at least one die pad, connection pad, or die contact 110, 110T (hereafter, “die contacts 110, 110T”). As shown in FIG. 1, each semiconductor die 104, 104T includes a die contact 110, 110T formed in semiconductor die 104, 104T and/or on the uncovered (portion) of top surface 106, 106T. For example, top semiconductor die 104T includes a plurality of die contacts 110T (shown in phantom in FIG. 1) formed directly in the top semiconductor die 104T and/or directly on the top surface 106T of the top semiconductor die 104T. Each distinct semiconductor die of the plurality of semiconductor dies 104 formed below and/or between top semiconductor die 104T and substrate 102 also includes a plurality of die contacts 110.

As shown in the non-limiting example, die contacts 110 are formed directly in respective semiconductor dies 104 and/or directly on the uncovered top surfaces 106 for each semiconductor die of the plurality of semiconductor dies 104. As discussed herein, the plurality of die contacts 110, 110T are used to electrically couple each of the distinct semiconductor dies 104, 104T to one another, and/or to electrically couple the semiconductor die(s) 104, 104T to substrate 102, via substrate contact 112 formed directly in and/or directly on substrate 102. Die contacts 110, 110T formed in the plurality of semiconductor dies 104, 104T are of a predetermined configuration and/or circuitry based on operational and/or structural parameters of semiconductor package 100. It is understood that the number of die contacts 110, 110T and/or the configuration of die contacts 110, 110T of semiconductor package 100 shown in FIGS. 1-3 is illustrative. As such, other non-limiting examples of semiconductor package 100 can include more or fewer die contacts 110, 110T and/or can include distinct configurations or circuitry than the non-limiting example shown in FIG. 1.

Semiconductor package 100 also includes a plurality of bond wires 118, 120 (shown partially in phantom in FIG. 1) for electrically connecting various components therein. More specifically, semiconductor package 100 includes bond wires 118 extending between, contacting, electrically connecting, and/or communicatively coupling the plurality of semiconductor dies 104, 104T to one another, and/or to substrate 102. As shown in the non-limiting example of FIGS. 1 and 3, each bond wire 118 extends between and/or directly contacts die contacts 110, 110T for two adjacent stacked semiconductor dies 104, 104T.

For example, bond wire 118T extends between, contacts, and/or electrically connects die contact 110T of the top semiconductor die 104T to the die contact 110 of the adjacent semiconductor die 104. Additionally, one bond wire of the plurality of bond wires 118 extends between and/or directly contacts substrate contact 112 and die contact 110 for the immediately adjacent semiconductor die of the plurality of stacked semiconductor dies 104. In the non-limiting example, bond wires 118 electrically connect, communicatively couple, and/or form a transmission path between each of the plurality of stacked semiconductor dies 104, 104T and substrate 102.

Additionally, bond wires 120 extend between, contact, electrically connect, and/or communicatively couple top semiconductor die 104T directly to substrate 102. As shown in FIGS. 1 and 2, each bond wire 120 extends between and/or directly contacts die contact 110T for top semiconductor die 104T and substrate contact 112 of substrate 102. In the non-limiting example, bond wires 120 electrically connect, communicatively couple, and/or form a transmission path between top semiconductor die 104T of the plurality of stacked semiconductor dies 104, 104T and substrate 102.

Bond wires 118, 120 are formed from any suitable material that includes conductive and/or electrical properties to form an electrical transmission path between different components of semiconductor package 100. In one example, bond wires 118, 120 are formed from gold (Au) wire. Additionally, the non-limiting example of semiconductor package 100 shown in FIG. 1 includes ten (10) bond wires 118, and two (2) bond wires 120. It is understood that the number of bond wires 118, 120 included in semiconductor package 100 is dependent, at least in part on, the number of semiconductor dies in the plurality of stacked semiconductor dies 104, 104T, the number of distinct plurality of stacked semiconductor dies 104, 104T, the number of die contacts 110, 110T, the number of substrate contacts 112, and/or the configuration/circuitry of the plurality of stacked semiconductor dies 104, 104T for semiconductor package 100.

A multi-layer film structure 122 is disposed over the plurality of stacked semiconductor dies 104, 104T. More specifically, and as shown in FIGS. 1-3, semiconductor package 100 includes the multi-layer film structure 122 disposed directly over top surface 106T of top semiconductor die 104T and/or a top surface of a molding compound 132 that encapsulates the plurality of stacked semiconductor dies 104, 104T. As such, no portion of the top surface 106T of top semiconductor die 104T is exposed and/or uncovered by the molding compound 132 and/or multi-layer film structure 122. In another example, top surface 106T of the top semiconductor die 104T is directly coupled to the multi-layer film structure 122. In either case, the multi-layer film structure 122 protects the top semiconductor die 104T and the semiconductor package 100 from short-circuiting or burning when the semiconductor package 100 is paired with other semiconductor packages or incorporated into a larger electronic device. The multi-layer film structure 122 also protects the top semiconductor die 104T from burning during a laser etching or other marking process.

In a non-limiting example, the multi-layer film structure 122 includes an insulative layer 124. The insulative layer 124 is disposed directly over, contacts, is coupled to, and/or adheres directly to the top surface of molding compound 132. In an example, at least a portion of bond wires 118, 120 contact and/or extend through insulative layer 124 of multi-layer film structure 122. More specifically, and as shown in FIG. 2, bond wire 120 includes a first portion 126 that contacts and/or is pressed down by insulative layer 124 of multi-layer film structure 122 and contacts die contact 110T. Although illustrated as contacting or abutting insulative layer 124 of multi-layer film structure 122, the first portion 126 may extend through and/or withing the insulative layer 124.

Additionally, and as shown in FIG. 3, bond wire 118T includes a first portion 128 abutting or contacting a bottom surface of insulative layer 124 of multi-layer film structure 122 while contacting (a distinct) die contact 110T of top semiconductor die 104T. Similar to the first portion 126, the first portion 128 may partially extend within the insulative layer 124.

Insulative layer 124 of multi-layer film structure 122 also includes and/or is formed with a predetermined height (H₁) of approximately 10 micrometers (µm) or less. Additionally, insulative layer 124 is formed from any suitable material that abuts, surrounds, encompasses, and/or envelops first portions 126, 128 of bond wires 120, 118T.

In a non-limiting example, insulative layer 124 of multi-layer film structure 122 is a solder mask, or any other appropriate insulative material. A solder mask is both insulative and has good adhesion with epoxy-molding compound and copper, additional components of the semiconductor package 100.

As the insulative layer 124 of the multi-layer film structure 122 is not electrically active, the first portion 126 of the bond wire 120 and the first portion 128 of the bond wire 118T can abut, extend into and/or be surrounded by the insulative layer 124 while retaining their electrical connectivity. Additionally, by contacting, receiving and surrounding the first portion 126 and the first portion 128, the insulative layer 124 facilitates reduction in a top loop or wire clearance for the semiconductor package 100. That is, the insulative layer 124 facilitates reduction in the space needed to accommodate the first portion 126 and the first portion 128 at the top surface 106T of the top semiconductor die 104T. This provides better tolerance for stacking multiple semiconductor packages 100 together. In some examples, the insulative layer 124 facilitates reduction of the top loop clearance to a thickness of 0 um or less (i.e., a negative top loop clearance in that the top loop is pressed on by the multi-layer film structure 122, a position or height of a portion of the top loop is lower that an initial position of the top loop post wire bonding, and/or a portion of the bond wire is at least partially disposed within a portion of the insulative layer 124).

As shown in FIG. 2, the first portions 126, 128 of bond wires 120, 118T do not extend into the insulative layer 124. Rather, there may be a gap present between the top surface 106T of the top semiconductor die 104T and the insulative layer 124 and the gap is filled, or partially filed with the molding compound 132. As such, the first portions 126, 128 of bond wires 120, 118T may contact a bottom of the insulative layer 124. Such contact with the bottom of the insulative layer 124 still protects the first portions 126, 128 of bond wires 120, 118T and the top semiconductor die 104T from die burn and other defects, as well as facilitating a reduction in necessary top clearance for the top semiconductor die 124.

The multi-layer film structure 122 also includes a resistant or resistive layer 130. Resistant layer 130 is disposed directly over insulative layer 124. More specifically, and as shown in FIGS. 1-3, resistant layer 130 is formed, disposed over, and/or substantially covers insulative layer 124, such that insulative layer 124 is positioned between resistant layer 130 and top surface 106T of top semiconductor die 104T for the plurality of stacked semiconductor dies 104, 104T formed in semiconductor package 100. Optionally, resistant layer 130 of the multi-layer film structure 122 may be exposed and/or form a portion of the top surface for semiconductor package 100.

The multi-layer film structure 122 further includes a marking layer 131. In an example, the marking layer 131 is an organic layer or a resin layer. The marking layer 131 is disposed directly over resistant layer 130. More specifically, and as shown in FIGS. 1-3, marking layer 131 is formed, disposed over, and/or substantially covers the resistant layer 130, such that the resistant layer 130 is positioned between the insulative layer 124 and the marking layer 131. Optionally, the marking layer 131 of the multi-layer film structure 122 may be exposed and/or form a portion of the top surface for semiconductor package 100.

Each of the insulative layer 124, the resistant layer 130, and the marking layer 131 of multi-layer film structure 122 includes and/or is formed with a predetermined height of approximately 10 micrometers (µm) or less. As such, an overall height (H₁ + H₂ + H₃) of the multi-layer film structure 122 is approximately 30 µm or less.

Resistant layer 130 is formed from any suitable material to protect and/or provide stability to insulative layer 124 of multi-layer film structure 122, as well as be marked in a laser etching process, such as when marking layer 131 is omitted. In a non-limiting example, resistant layer 130 of multi-layer film structure 122 can be composed of metals, metal alloys, or any other similar material. In a specific example, the resistant layer 130 is formed of copper. Marking layer 131 is formed of any suitable material that can be marked in a laser etching process while also protecting the resistant layer 130 and semiconductor package 100. In a non-limiting example, marking layer 131 can be composed of metallic compounds, resins, Teflon, solder mask, or other organic materials. In a specific example, the marking layer 131 is omitted, such as when a green laser is utilized to mark the semiconductor package 100.

Turning to FIGS. 2 and 3, semiconductor package 100 also includes a molding compound 132. Molding compound 132 is disposed over various portions and/or components of semiconductor package 100. More specifically, molding compound 132 is disposed over exposed portions of substrate 102, substrate contacts 112, and at least a portion of the plurality of stacked semiconductor dies 104. As shown in the non-limiting example, molding compound 132 is disposed directly over exposed surfaces 106 of the plurality of stacked semiconductor dies 104 positioned between top semiconductor die 104T and substrate 102, die contacts 110 formed in the exposed surfaces 106, and the sidewalls of the plurality of stacked semiconductor dies 104, 104T. Additionally, molding compound 132 is also formed adjacent and/or over the top surface 106T of top semiconductor die 104T. That is, in the example, molding compound 132 is formed directly adjacent to, but does not cover, top surface 106T of top semiconductor die 104T, as well as insulative layer 124 and resistant layer 130 forming multi-layer film structure 122.

In another example, such as when there is a gap or a space between the top surface 106T of top semiconductor die 104T and the insulative layer 124, the molding compound 132 is provided within the gap and at least partially covers the die contacts 110 and/or exposed portions of the bond wires 118, 118T, including loop portion of the bond wires 118, 118T. As shown in FIGS. 2 and 3, molding compound 132 and resistant layer 130 of multi-layer film structure 122 are substantially planar and/or in planar alignment to collectively form the top surface of semiconductor package 100.

Molding compound 132 is also formed over at least distinct portions of bond wires 118, 118T, 120. Turning to FIG. 2, molding compound 132 is formed over a second portion 134 of bond wire 120. More specifically, bond wire 120 includes second portion 134, formed adjacent first portion 126, that is disposed within and/or extends through molding compound 132. As such, second portion 134 of bond wire 120, extending between first portion 126 and substate contact 112, is substantially surrounded by and/or embedded within molding compound 132.

As shown in FIG. 3, bond wires 118 extending between substrate contact 112 and die contacts 110, as well as bond wires 118 extending between distinct die contacts 110 formed in stacked semiconductor dies 104, are also disposed within, embedded in, and/or extend through molding compound 132, such that molding compound 132 substantially surrounds bond wires 118. Additionally, bond wire 118T extending between die contact 110T formed on top semiconductor die 104T and the adjacent stacked die 104 includes a second portion 136, formed adjacent first portion 128. Molding compound 132 is formed over second portion 136 of bond wire 118T. More specifically, bond wire 118T includes second portion 136 that is disposed within and/or extends through molding compound 132. In the non-limiting example, second portion 134 of bond wire 118T is substantially surrounded by and/or embedded within molding compound 132.

Molding compound 132 is formed from any suitable material that can be disposed over the respective portions of semiconductor package 100 to surround those portions, as discussed herein. In a non-limiting example, molding compound 132 is formed from an epoxy-based resin, using phenolic resins, polyester resins, polyamide resins, etc. as the main body, combined with epoxy resins such as o-cresol aldehyde epoxy resin, bromine-containing epoxy resin, biphenyl-type epoxy resin, dicyclopentadienyl-type epoxy resin and other epoxy resins. In other examples, molding compound 132 can also be combined with linear phenolic resins, curing agents such as anhydrides and polyamines, curing accelerators such as amines, imidazoles and phosphines, flame retardants such as antimony compounds and bromides, mold releasing agents, fillers and coloring agents.

The inclusion of multi-layer film structure 122 provides added benefits to semiconductor package 100. For example, and as discussed herein, insulative layer 124 of multi-layer film structure 122 contacts and/or receives first portion 126, 128 of bond wires 120, 118T therein and substantially prevents short-circuiting of bond wires 118T, 120 after formation of semiconductor package 100. As a result, the insulative layer 124 of multi-layer film structure 122 also prevents and/or reduces the occurrence of die burning of the top semiconductor die 104T of the plurality of stacked semiconductor dies 104.

In an example, causing the bond wires 118T, 120 to contact a bottom surface of the insulative layer 124, reduces the loop height of bond wires 118T, 120 without reducing the desired spacing for bond wires 118T, 120 within semiconductor package 110. The reduction in the loop height of bond wires 118T, 120 allows for the overall height or thickness of semiconductor package 100 to be reduced as well. The use of resistant layer 130 in multi-layer film structure 122 provides additional protection and/or stability to insulative layer 124. Despite the reduced thickness of semiconductor packages 100 including multi-layer film structure 122, the semiconductor packages 100 retain their operational performance and operational longevity.

Although FIGS. 1-3 show the multi-layer film structure 122 extending entirely across the molding compound 132, the multi-layer film structure 122 may extend partially across the molding compound 132. For example, the multi-layer film structure 122 may extend over areas that include top portions of various bond wires.

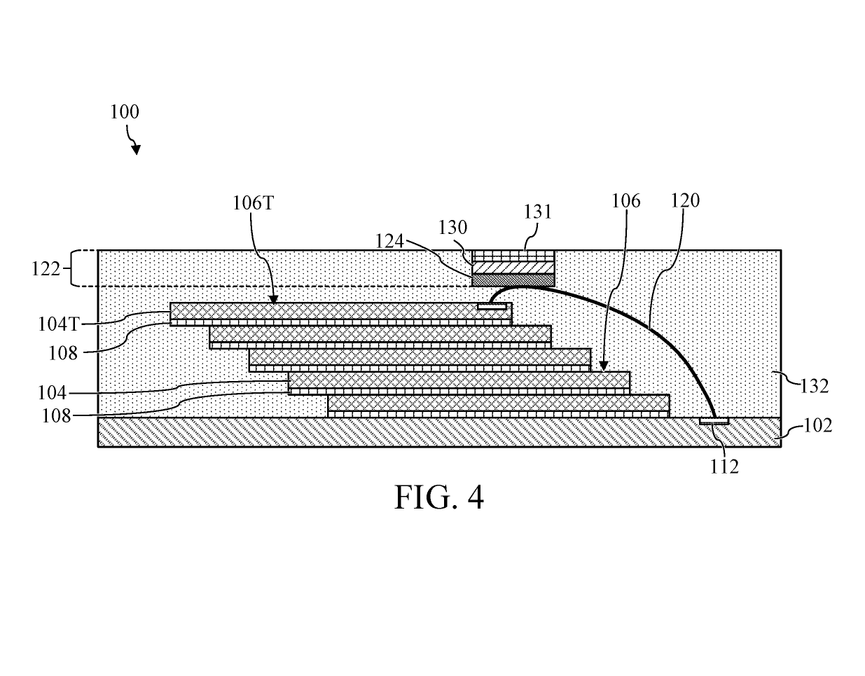

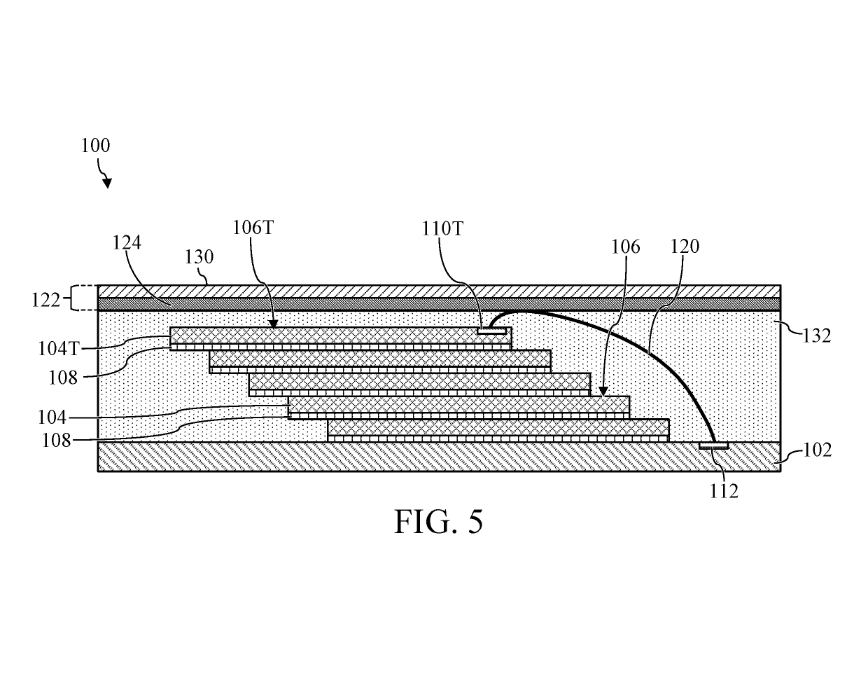

FIGS. 4-5 show cross-sectional front views of additional examples of semiconductor package 100. It is understood that similarly numbered and/or named components may function in a substantially similar fashion. Redundant explanation of these components has been omitted for clarity and/or brevity.

In the non-limiting example shown in FIG. 4, molding compound 132 surrounds the entirety of the semiconductor package 100, including the sidewalls of the multi-layer film structure 122. In this example, the multi-layer film structure 122 is only provided over a portion of the bond wire 120 and the molding 132 forms the rest of the top of the semiconductor package 100. In the non-limiting example shown in FIG. 5, the multi-layer film structure 122 includes the insulative layer 124 and the resistant layer 130 and omits the marking layer 131. In this example, the resistant layer 130 forms a portion of the top of the semiconductor package 100. Molding compound 132 is positioned about the semiconductor package 100 but does not cover the resistant layer 130. The resistant layer 130 may be etched or otherwise marked through a laser etching process.

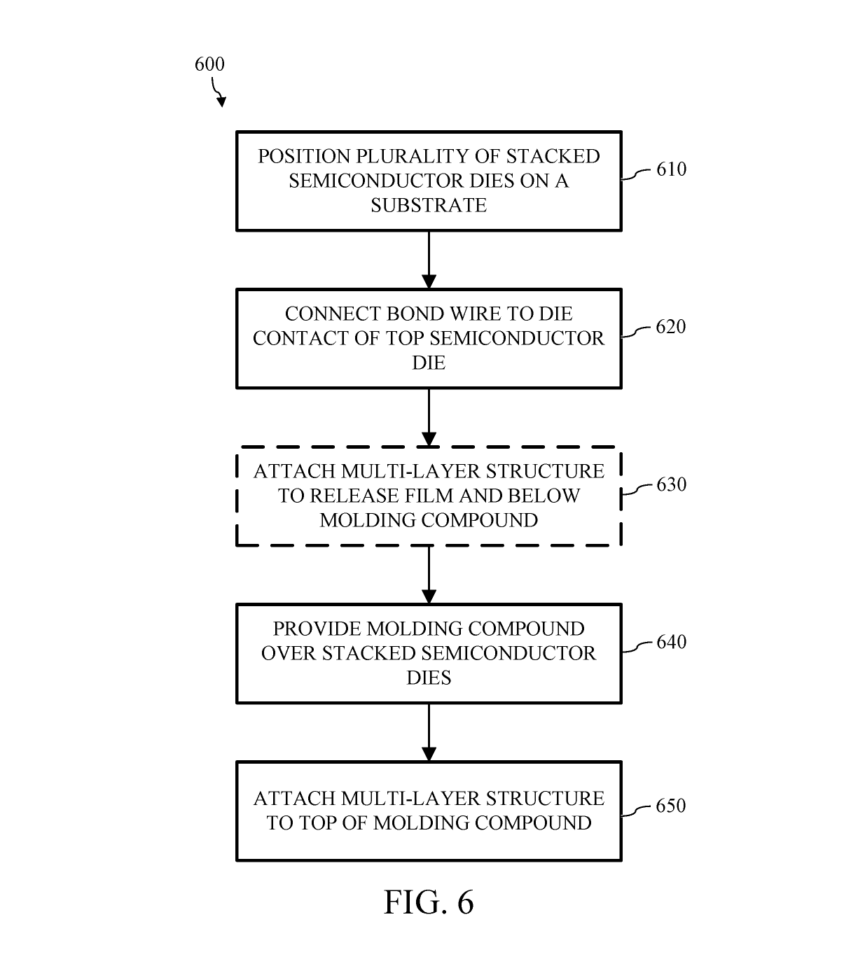

FIG. 6 illustrates a method 600 for creating a semiconductor package. Specifically, FIG. 6 is a flowchart depicting one example process for creating a semiconductor package including a multi-layer film structure. In some examples, the operations form the various non-limiting examples of semiconductor package 100, as discussed above with respect to FIGS. 1-5.

The method 600 begins when a plurality of stacked semiconductor dies are positioned (610) on a substrate. More specifically, the plurality of stacked semiconductor dies are disposed over, positioned on, and/or formed above the substrate in a staggered and/or stepped arrangement. As such, at least a portion of a top surface for each stacked semiconductor die is uncovered by adjacent semiconductor dies. Additionally, a top semiconductor die of the plurality of stacked semiconductor dies, positioned above the substrate, includes a top surface that is completely uncovered and/or exposed. Each semiconductor die of the plurality of stacked semiconductor dies, including the top semiconductor die, includes at least one die contact formed directly in and/or directly on the exposed (portion of the) top surface. Substrate also includes at least one substrate contact formed therein and/or thereon. Die contact(s) and substrate contact(s) are formed in a predetermined configuration, dependent on semiconductor package’s device type (e.g., NAND memory device).

One or more bond wires are then connected (620) to the die contact formed in/on top semiconductor die of the plurality of stacked semiconductor dies. More specifically, a bond wire is connected, contacted, and/or electrically/communicatively coupled to the die contact formed in/on the top surface of the top semiconductor die, and extends away from the top surface of top semiconductor die. In a non-limiting example, the bond wire connected to the die contact of top semiconductor die includes a first portion directly connected to and positioned substantially adjacent the die contact. Depending on the configuration of the die contacts and substrate contacts, the bond wire connected to the die contact of top semiconductor die can extend toward an adjacent die contact formed in and/or on an adjacent semiconductor die of the plurality of stacked semiconductor dies, or alternatively can extend toward a substrate contact formed in and/or on the substrate.

In an example, compression molding may be used to form the molding compound over the stacked semiconductor dies and bond wires. In such an example, a multi-layer structure is coupled (630) to a release film and a molding compound is provided over the multi-layer film structure. In an example, the molding compound, the multi-layer film structure and the release film is provided in a cavity block of a compression molding machine. The molding compound is then provided (640) over the stacked semiconductor dies. For example, the molding compound is provided within a mold (e.g., a lower cavity or block) where the mold also holds the multi-layer film structure. Specifically, the multi-layer film structure may be positioned within the mold and the molding compound may be positioned over the multi-layer film structure. In this example, when the semiconductor package is pressed into the mold (e.g., pressed from an upper cavity or block into the lower cavity or block), the semiconductor package will be pressed directly into the molding compound. The multi-layer film structure, attached and/or otherwise coupled to the molding compound, will form the top or upper surface of the semiconductor package. When the compression molding process is complete, the release layer releases the multi-layer structure which causes the multi-layer structure to be attached (650) to the top of the semiconductor package, including the molding compound.

In another example, the molding compound is provided over the stacked semiconductor dies in any suitable manner. When the molding compound has been disposed over the various structures, the various layers of the multi-layer structure are provided over and/or on the top surface of the molding compound.

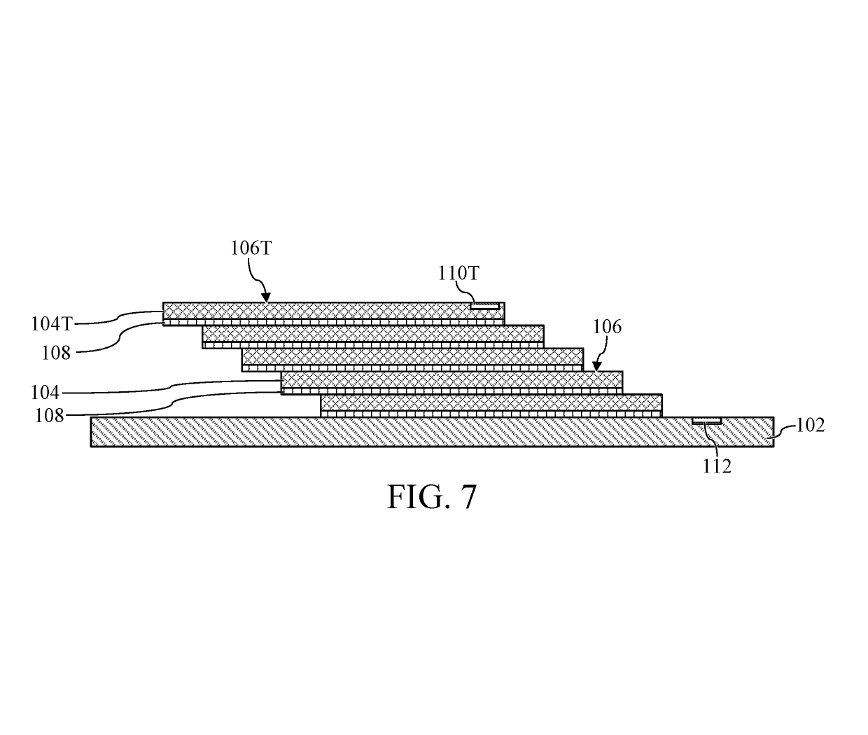

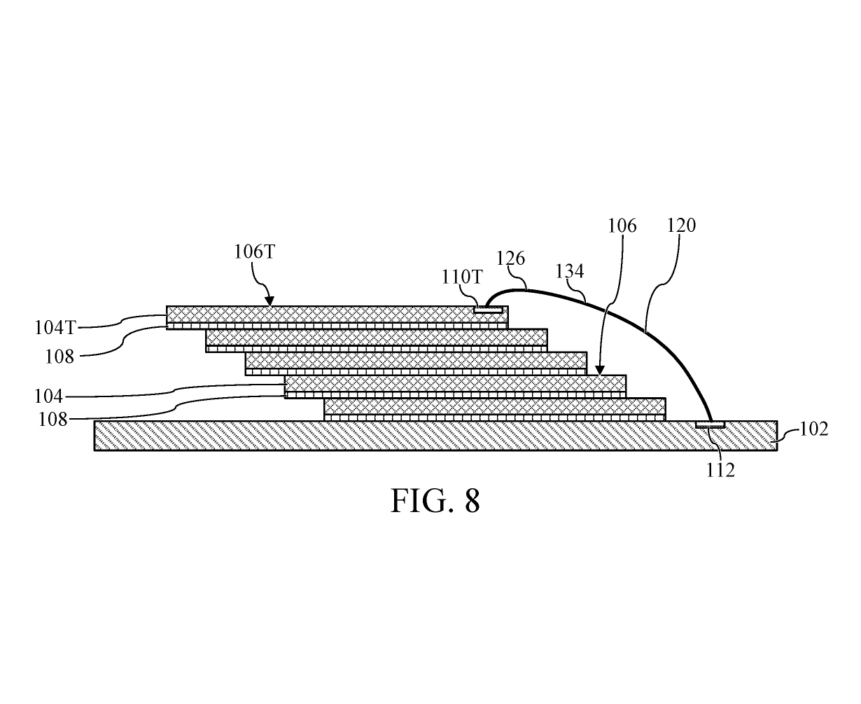

FIGS. 7-10 show various processes for creating semiconductor package 100 shown and described herein. More specifically, FIGS. 7-10 show cross-sectional front views of semiconductor components or parts undergoing the various operations described with respect to FIG. 6. The non-limiting example shown in FIGS. 7-10 depicts a section of semiconductor package 100 that includes bond wire 120 (see e.g., FIG. 8) extending from top surface 106T of top semiconductor die 104T to substrate contact 112 of substrate 102. It is understood that other sections of semiconductor package 100 (e.g., sections including bond wires 118, 118T) undergo similar processes of creation, as discussed herein. Additionally, it is understood that similarly numbered and/or named components may function in a substantially similar fashion. Redundant explanation of these components has been omitted for clarity and/or brevity.

FIG. 7 shows a cross-sectional front view of the plurality of stacked semiconductor dies 104, 104T being disposed over substrate 102. More specifically, the plurality of stacked semiconductor dies 104, 104T are disposed over, positioned on, and/or formed above substrate 102 in a staggered and/or stepped arrangement. As shown, at least a portion of top surface 106, 106T for each stacked die 104, 104T is uncovered by adjacent semiconductor dies. Additionally, top semiconductor die 104T of the plurality of stacked semiconductor dies 104, 104T, positioned above substrate 102, includes top surface 106T that is completely uncovered and/or exposed in FIG. 7. As discussed herein, each semiconductor die of the plurality of stacked semiconductor dies 104, 104T, including top semiconductor die 104T, includes at least one die contact 110 (not shown), 110T formed directly in and/or directly on the exposed (portion of the) top surface 106, 106T. Substrate 102 also includes substrate contacts 112 formed therein and/or thereon. FIG. 7 corresponds to operation 610 shown and described with respect to FIG. 6.

FIG. 8 shows bond wire 120 connected to die contact 110T formed in/on top semiconductor die 104T of the plurality of stacked semiconductor dies 104, 104T. More specifically, bond wire 120 is connected, contacts, and/or electrically/communicatively coupled to die contact 110T formed in/on top surface 106T of top semiconductor die 104T and extends away from top surface 106T of top semiconductor die 104T. In the non-limiting example shown, bond wire 120 connected to die contact 110T of top semiconductor die 104T includes a first portion 126 directly connected to and positioned substantially adjacent die contact 110T, and second portion 134 formed adjacent first portion 126. Bond wire 120 extends toward substrate 102, and second portion 134 of bond wire 120 is connected, contacts, and/or electrically coupled to substrate contact 112 formed in and/or on substrate 102. FIG. 8 corresponds to operation 620 shown and described with respect to FIG. 6.

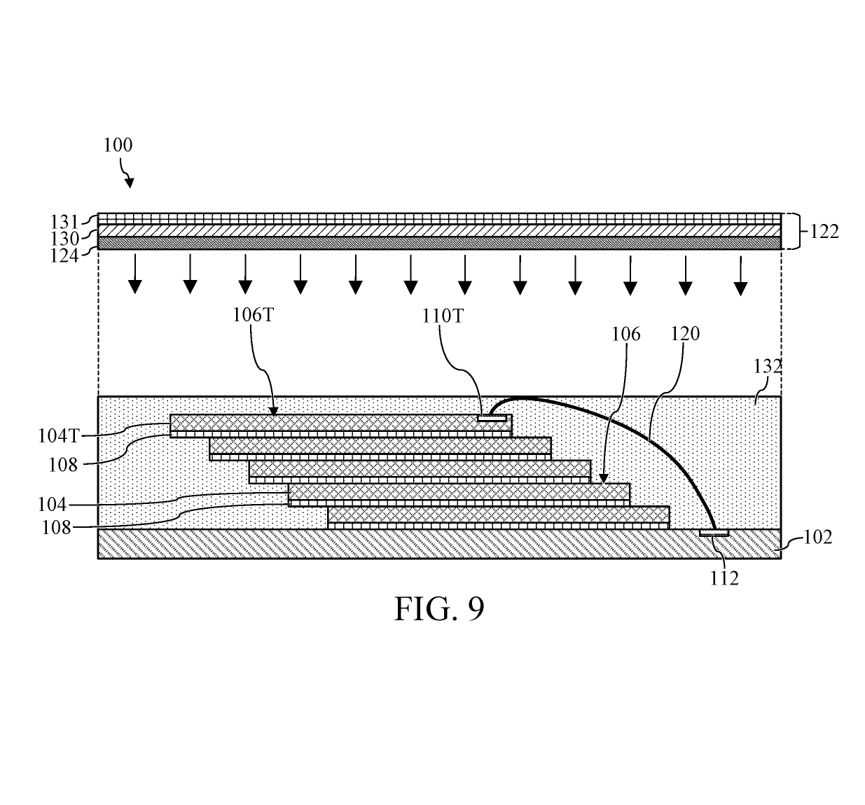

FIG. 9 shows a molding compound 132 being disposed over the plurality of stacked semiconductor dies 104, 104T. In an example, any suitable molding compound application process may be used to encapsulate the plurality of stacked semiconductor dies 104, 104T. In an example, FIG. 9 corresponds to operation 640 shown and described with respect to FIG. 6. When the molding compound 132 has been provided over the plurality of stacked semiconductor dies 104, 104T, the multi-layer film structure 122 is provided on a top surface of the molding compound 132.

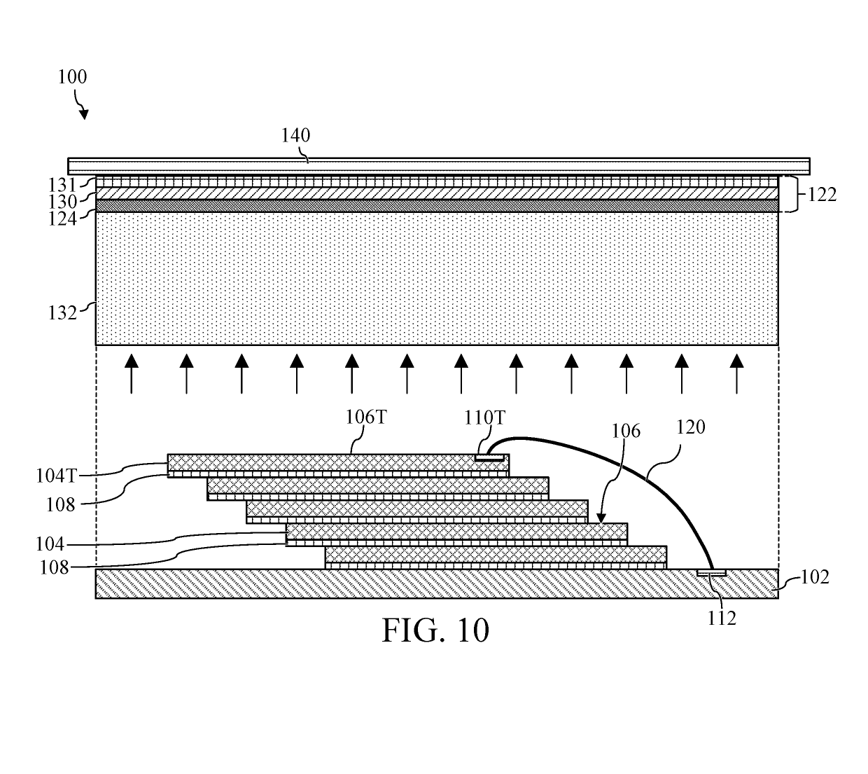

Turning to FIG. 10, in another example, a compression molding process may be used to encapsulate the plurality of stacked semiconductor dies 104, 104T. For example, the multi-layer film structure 122 is provided within a cavity of a compression molding machine and the top layer (e.g., the marking layer 131) of the multi-layer film structure 122 contacts a multi-layer film release film 140 within the cavity. A molding compound 132 is also provided within the cavity and contacts the insulative layer 124 of multi-layer film structure 122.

The plurality of stacked semiconductor dies 104, 104T is then inserted into the molding compound 132 as part of a compression molding process. When the molding compound has cured, the multi-layer film release film 140 releases the multi-layer film structure 122 when the semiconductor package 100 is removed from the cavity (or moved in a direction opposite the arrows).

As discussed herein, incorporation of the multi-layer film structure 122 with the semiconductor package 100 both protects semiconductor package 100 from experiencing die burn and other defects, and facilitates reduced top clearance (both reduced top bond wire or loop clearance and top semiconductor die clearance) for the semiconductor package 100. By disposing the insulative layer 124 directly on the top surface 106T of top semiconductor die 104T, the insulative layer 124 reduces the necessary top loop clearance. Specifically, a first portion 126, 128 or bond wires 118, 120 is received within the insulative layer 124. Thus, the insulative layer 124 can reduce the top loop clearance to 0 um or less (e.g., a negative top loop clearance).

Additionally, the resistant layer 130 eliminates top semiconductor die burn. This allows the semiconductor package 100 to be positioned closely to other conducting structures (e.g., a second semiconductor package 100, etc.) while retaining the full functionality of the semiconductor package 100. When the resistant layer 130 forms the top surface of the semiconductor package 100, the resistant layer 130 resists marking during a laser etching process, further protecting the other components of the semiconductor package 100. The marking layer 131 protects the resistant layer 130 and facilitates marking or etching of the semiconductor package 100.

By incorporating the multi-layer film structure 122 within a mold (e.g., a lower block or cavity of a molding apparatus), the multi-layer film structure 122 can be applied to the semiconductor package 100 during a typical manufacturing process. Additionally, the multi-layer film structure 122 bonds or adheres well to the molding compound 132 used in creating the semiconductor package 100. Each layer 124, 130, 131 of the multi-layer film structure 122 may have a thickness of approximately 10 um or less, resulting in the multi-layer film structure 122 having a thickness of approximately 30 um or less.

Based on the above, examples of the present disclosure describe a semiconductor package, comprising: a substrate; a plurality of stacked semiconductor dies disposed over the substrate, the plurality of stacked semiconductor dies including: a top semiconductor die positioned above the substrate, the top semiconductor die including: a top surface; and a semiconductor die contact formed on the top surface; a multi-layer film structure disposed over the top semiconductor die, the multi-layer film structure including: an insulative layer disposed directly over the top surface of the top semiconductor die; and a metallic layer disposed directly over the insulative layer; and a bond wire contacting the semiconductor die contact of the top semiconductor die, wherein at least a portion of the bond wire contacts the insulative layer of the multi-layer film structure. In an example, a portion of the bond wire is pressed downward by the insulative layer of the multi-layer film structure. In an example, the multi-layer film further includes a marking layer disposed directly over the metallic layer. In an example, the marking layer comprises resin. In an example, the marking layer comprises Teflon. In an example, the metallic layer comprises copper. In an example, the metallic layer eliminates a burn risk of the top semiconductor die. In an example, the insulative layer comprises a solder mask. In an example, the multi-layer film has a thickness of 30 um or less. In an example, a top loop clearance of the bond wire is 0 um or less.

Other examples describe a method of manufacturing a semiconductor package, comprising: disposing a plurality of stacked semiconductor dies on a substrate, the plurality of stacked semiconductor dies including: a top semiconductor die positioned above the substrate, the top semiconductor die including a top surface; and a semiconductor die contact formed on the top surface; connecting a portion of a bond wire to the semiconductor die contact of the top semiconductor die; disposing a multi-layer film structure directly over the top semiconductor die of the plurality of stacked semiconductor dies, an insulative layer of the multi-layer film structure contacting the portion of the bond wire connected to the semiconductor die contact of the top semiconductor die. In an example, disposing the multi-layer film structure directly over the top semiconductor die of the plurality of stacked semiconductor dies comprises pressing the plurality of stacked semiconductor dies into the insulative layer of the multi-layer film structure, such that the insulative layer contacts the top surface of the top semiconductor die and presses downward on the portion of the bond wire connected to the semiconductor die contact of the top semiconductor die. In an example, the method also includes removing a release film coupled to the multi-layer film structure and wherein removing the release film coupled to the multi-layer film structure comprises removing the release film from a metallic layer of the multi-layer film structure, the metallic layer disposed directly on the insulative layer. In an example, removing the release film coupled to the multi-layer film structure comprises removing the release film from a marking layer of the multi-layer film structure, the marking layer disposed directly on a metallic layer and the metallic layer disposed directly on the insulative layer. In an example, disposing a multi-layer film structure directly over the top semiconductor die of the plurality of stacked semiconductor dies reduces a top die clearance for the semiconductor package. In an example, the method also includes prior to disposing the multi-layer film structure directly over the top semiconductor die, disposing an epoxy molding compound over the top semiconductor die. In an example, the multi-layer film structure is disposed on the epoxy molding compound.

Examples also describe an encapsulated semiconductor package, comprising: a substrate including a first contact means; a plurality of stacked semiconductor dies disposed over the substrate, the plurality of stacked semiconductor dies including: a top semiconductor die positioned above the substrate, the top semiconductor die including: a top surface; and a second contact means provided on the top surface; a connection means extending between and electrically connecting the second contact means of the top semiconductor die and the first contact means of the substrate; an insulative means disposed directly over the top semiconductor die, the insulative means contacting a portion of the connection means; and a resistance means disposed directly over the insulative means. In an example, the encapsulated semiconductor package also includes a marking layer means disposed directly over the resistance means. In an example, the insulative means presses downward on a portion of the connection means.

The foregoing drawings show some of the processing associated according to several embodiments of this disclosure. In this regard, each drawing or block within a flow diagram of the drawings represents a process associated with embodiments of the method described. It should also be noted that in some alternative implementations, the acts noted in the drawings or blocks may occur out of the order noted in the figure or, for example, may in fact be executed substantially concurrently or in the reverse order, depending upon the act involved. Also, one of ordinary skill in the art will recognize that additional blocks that describe the processing may be added.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” and/or “substantially” as applied to a particular value of a range applies to both values, and unless otherwise dependent on the precision of the instrument measuring the value, may indicate +/- 10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A semiconductor package, comprising:
a substrate;
a plurality of stacked semiconductor dies disposed over the substrate, the plurality of stacked semiconductor dies including:
a top semiconductor die positioned above the substrate, the top semiconductor die including:
a top surface; and
a semiconductor die contact formed on the top surface;
a multi-layer film structure disposed over the top semiconductor die, the multi-layer film structure including:
an insulative layer disposed directly over the top surface of the top semiconductor die; and
a metallic layer disposed directly over the insulative layer; and
a bond wire contacting the semiconductor die contact of the top semiconductor die, wherein at least a portion of the bond wire contacts the insulative layer of the multi-layer film structure.

2. The semiconductor package of claim 1, wherein a portion of the bond wire is pressed downward by the insulative layer of the multi-layer film structure.

3. The semiconductor package of claim 1, wherein the multi-layer film further includes a marking layer disposed directly over the metallic layer.

4. The semiconductor package of claim 3, wherein the marking layer comprises resin.

5. The semiconductor package of claim 3, wherein the marking layer comprises Teflon.

6. The semiconductor package of claim 1, wherein the metallic layer comprises copper.

7. The semiconductor package of claim 6, wherein the metallic layer eliminates a burn risk of the top semiconductor die.

8. The semiconductor package of claim 1, wherein the insulative layer comprises a solder mask.

9. The semiconductor package of claim 1, wherein the multi-layer film has a thickness of 30 um or less.

10. The semiconductor package of claim 1, wherein a top loop clearance of the bond wire is 0 um or less.

11. A method of manufacturing a semiconductor package, comprising:
disposing a plurality of stacked semiconductor dies on a substrate, the plurality of stacked semiconductor dies including:
a top semiconductor die positioned above the substrate, the top semiconductor die including a top surface; and
a semiconductor die contact formed on the top surface;
connecting a portion of a bond wire to the semiconductor die contact of the top semiconductor die; and
disposing a multi-layer film structure directly over the top semiconductor die of the plurality of stacked semiconductor dies, an insulative layer of the multi-layer film structure contacting the portion of the bond wire connected to the semiconductor die contact of the top semiconductor die.

12. The method of claim 11, wherein disposing a multi-layer film structure directly over the top semiconductor die of the plurality of stacked semiconductor dies comprises pressing the plurality of stacked semiconductor dies onto the insulative layer of the multi-layer film structure, such that the insulative layer presses downward on the portion of the bond wire connected to the semiconductor die contact of the top semiconductor die.

13. The method of claim 11, further comprising removing a release film coupled to the multi-layer film structure and wherein removing the release film coupled to the multi-layer film structure comprises removing the release film from a metallic layer of the multi-layer film structure, the metallic layer disposed directly on the insulative layer.

14. The method of claim 13, wherein removing the release film coupled to the multi-layer film structure comprises removing the release film from a marking layer of the multi-layer film structure, the marking layer disposed directly on a metallic layer and the metallic layer disposed directly on the insulative layer.

15. The method of claim 11, wherein disposing a multi-layer film structure directly over the top semiconductor die of the plurality of stacked semiconductor dies reduces a top die clearance for the semiconductor package.

16. The method of claim 11, further comprising, prior to disposing the multi-layer film structure directly over the top semiconductor die, disposing an epoxy molding compound over the top semiconductor die.

17. The method of claim 16, wherein the multi-layer film structure is disposed on the epoxy molding compound.

18. An encapsulated semiconductor package, comprising:
a substrate including a first contact means;
a plurality of stacked semiconductor dies disposed over the substrate, the plurality of stacked semiconductor dies including:
a top semiconductor die positioned above the substrate, the top semiconductor die including:
a top surface; and
a second contact means provided on the top surface;
a connection means extending between and electrically connecting the second contact means of the top semiconductor die and the first contact means of the substrate;
an insulative means disposed directly over the top semiconductor die, the insulative means contacting a portion of the connection means; and
a resistance means disposed directly over the insulative means.

19. The encapsulated semiconductor package of claim 18, further comprising a marking layer means disposed directly over the resistance means.

20. The encapsulated semiconductor package of claim 19, wherein the insulative means presses downward on a portion of the connection means.
